(19) United States
(12) Patent Application Publication
(10) Pub. No.: US 2025/0351550 A1
(43) Pub. Date: Nov. 13, 2025

(54) STACKED MULTI-GATE DEVICE WITH CONTACT FEATURE AND METHODS FOR FORMING THE SAME

(71) Applicant: Taiwan Semiconductor Manufacturing Company, Ltd., Hsinchu (TW)

(72) Inventors: Che Chi Shih, Taoyuan City (TW); Szu-Hua Chen, Tainan City (TW); I-Hsuan Lo, Hsinchu City (TW); Ku-Feng Yang, Hsinchu County (TW); Wei-Yen Woon, Taoyuan City (TW); Szuya Liao, Hsinchu (TW)

(21) Appl. No.: 19/279,249

(22) Filed: Jul. 24, 2025

Related U.S. Application Data
(63) Continuation of application No. 18/437,635, filed on Feb. 9, 2024.

(51) Int. Cl. H10D 84/03; H01L 21/02; H10D 87/00; H10D 88/00

(52) U.S. Cl. CPC H10D 84/038; H10D 87/00; H10D 88/01; H01L 21/0234

(57) ABSTRACT

Methods and devices that include forming a first epitaxial region and a second epitaxial region above the first epitaxial region. An opening may be formed extending from the first region to the second region. And a liner layer is deposited on a sidewall and a bottom of the opening. A plasma treatment is performed on the liner layer, which can form a conditioned or passivated region of the first epitaxial region that may be maintained during the growth of additional epitaxial material on the second epitaxial region.

### CROSS-REFERENCE TO RELATED APPLICATIONS

This application is a continuation of U.S. patent application Ser. No. 18/437,635 filed Feb. 9, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. And they have become popular and promising candidates for high performance and low leakage applications. A multi-gate transistor has a gate structure that can extend, partially or fully, around a channel region to provide access to the channel region on two or more sides. Because its gate structure surrounds the channel regions, some multi-gate transistors be referred to as a surrounding gate transistor (SGT) or a gate-all-around (GAA) transistor. The channel region of such transistors may be formed from nanowires, nanosheets, other nanostructures, and/or other suitable structures. The shapes of the channel region have also given transistors alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues are leading to development of stacked device structure configurations, such as complementary field effect transistors (C-FET) where a first type of transistor (e.g., n-type multi-gate transistor) and a second type of transistor (e.g., p-type multi-gate transistor) are stacked vertically. While existing C-FET structures are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a C-FET device including source/drain contacts, according to one or more aspects of the present disclosure.

FIG. 2 illustrates fragmentary representative perspective view of a device such as a C-FET device fabricated according to aspects of the method of FIG. 1;

FIGS. 3A, 4A, 5A, 6A, 7A, 8A, 9A, 10A, 11A, 12A, 13A, and 14A illustrate fragmentary cross-sectional views of a device undergoing various fabrication processes in the method of FIG. 1 and along cut A-A of FIG. 2, according to one or more aspects of the present disclosure;

FIGS. 3B, 4B, 5B, 6B, 7B, 8B, 9B, 10B, 11B, 11C, 11D, 12B, 12C, 12D, 13B, 13C, 13D, 14B, 14C, and 14D illustrate fragmentary cross-sectional views of a device undergoing various fabrication processes in the method of FIG. 1 and along cut B-B of FIG. 2, according to one or more aspects of the present disclosure; and

FIGS. 15A, 15B, 15C, 15D, 15E, 15F, 15G, 15H illustrate fragmentary cross-sectional views of a surface of a semiconductor feature undergoing various fabrication processes according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

A stacked multi-gate device refers to a semiconductor device that includes a first multi-gate device and a second multi-gate device stacked over the first multi-gate device. When the first multi-gate device and the second multi-gate device are of different conductivity types, the stacked multi-gate device may be a complementary field effect transistor (C-FET). The multi-gate devices in a C-FET may be GAA transistors. The present disclosure is illustrated through a plurality of embodiments of a C-FET device. However, one appreciates other device types that may benefit from the present disclosure.

The vertical stacking of some device types such as C-FET can create challenges providing contacts to features within the stack. In some instances, a contact feature may extend through a source/drain feature of an upper device to contact a source/drain feature of a lower device. Exposure of the top source/drain feature and the bottom source/drain feature creates challenges in selectively processing one feature, while avoiding processing of another feature. For example, additional epitaxial material may be desired on a bottom source/drain feature, but undesired on a top source/drain feature. The present disclosure provides process to selectively deposit epitaxial material on a bottom source/drain feature with minimal or no impact to the upper source/drain feature. This may allow contact metal and silicide to be effectively and efficiently formed to provide contacts having sufficiently low contact resistance to provide for a desired C-FET device.

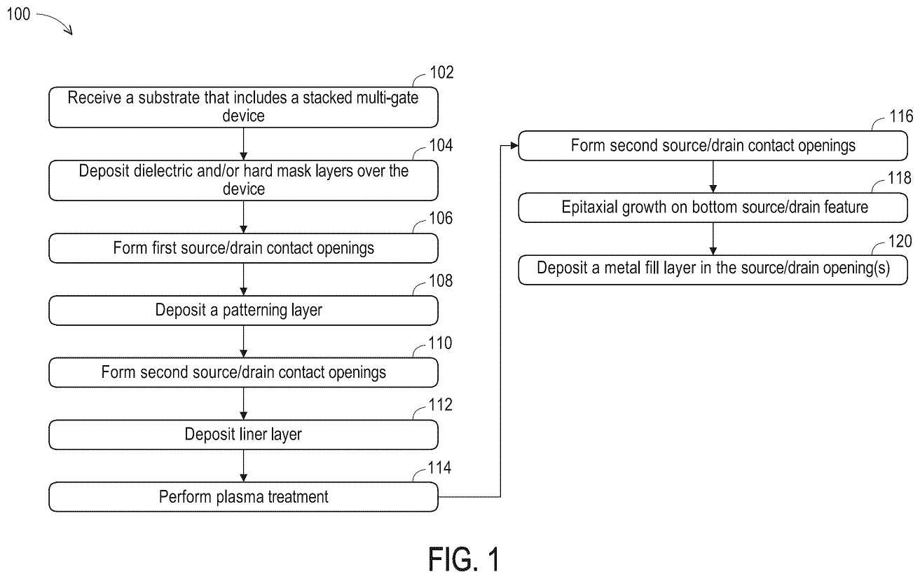

The various aspects of the present disclosure will now be described in more detail with reference to the figures. In that regard, FIG. 1 is a flowchart illustrating method 100 for forming a device having a stacked multi-gate structure and including source/drain contacts. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity.

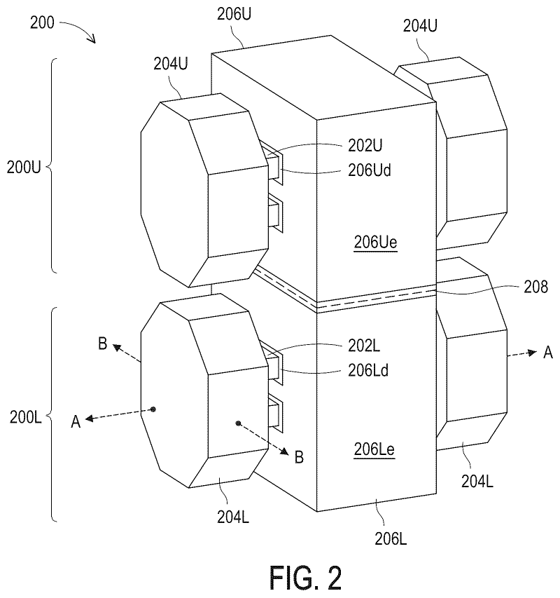

Method 100 is described below in conjunction with FIGS. 2A-14D, which are fragmentary cross-sectional views of a device 200 at different stages of fabrication according to embodiments of method 100. Throughout the present application, like reference numerals denote like features, unless otherwise excepted. Source/drain region(s) or feature(s) may refer to a source or a drain, individually or collectively dependent upon the context.

The method 100 includes a block 102 where a substrate having a semiconductor device such as a C-FET device disposed thereon is provided. For ease of reference, FIG. 2 provides a perspective view of a device 200 that is a C-FET device. The C-FET device 200 includes a lower device 200L (e.g., a p-type transistor) and an upper device 200U (e.g., an n-type transistor) over the lower device 200L. The lower and upper devices may be of opposite type (e.g., n-type/p-type). The lower device 200L includes source/drain features 204L (e.g., p-type epitaxial source/drain features), a plurality of channel layers 202L, and a gate structure 206L wrapping the channel layers 202L. The gate structure 206L includes a gate dielectric layer 206Ld and a gate electrode layer 206Le. The upper device 200U includes source/drain features 204U (e.g., n-type epitaxial source/drain features), a plurality of channel layers 202U, and a gate structure 206U wrapping the channel layers 202U. The gate structure 206U includes a gate dielectric layer 206Ud and a gate electrode layer 206Ue. An isolation layer 208 is disposed between the upper device 200U and the lower device 200L and isolates the gate structure 206L from the gate structure 206U. The configuration of the device 200 is exemplary only and not intended to be limiting. For example, two channel layers 202 are illustrated in each device for ease of illustration, but any number and configuration of channel layers may be provided based on the desired implementation. It is understood that some features are omitted in this figure for ease of understanding.

The device 200 of FIG. 2 illustrates two cross-sectional cuts. A first cross-sectional cut is provided along plane A-A, which extends through the source/drain and channel regions of the C-FET device. A second cross-sectional cut is provided along plane B-B, which is through the source/drain feature of the C-FET and perpendicular to the cut A-A.

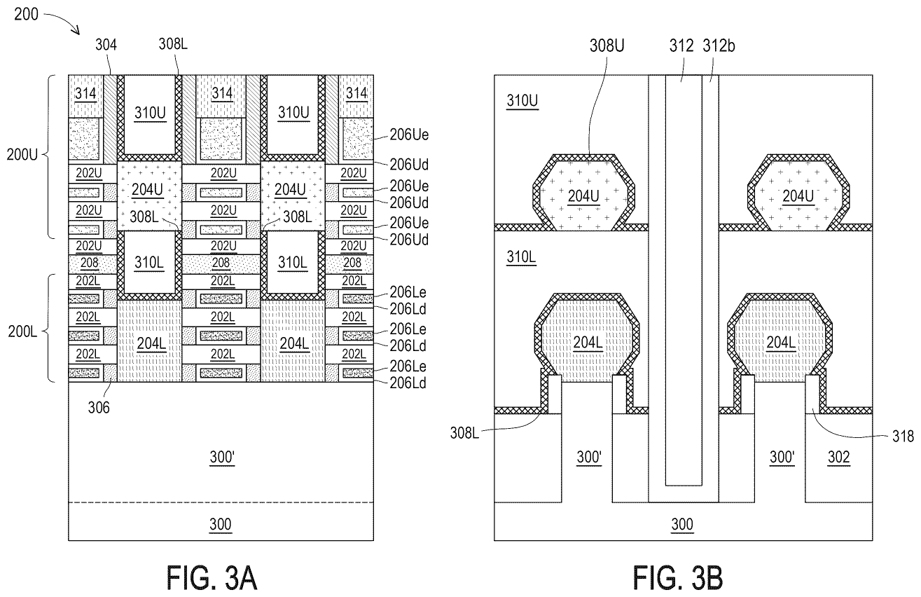

FIGS. 3A, 4A, 5A, 6A, 7A, 8A, 9A, 10A, 11A, 12A, 13A, and 14A illustrate fragmentary cross-sectional views of a device undergoing various fabrication processes in the method of FIG. 1 and along cut A-A of FIG. 2; FIGS. 3B, 4B, 5B, 6B, 7B, 8B, 9B, 10B, 11B, 11C, 11D, 12B, 12C, 12D, 13B, 13C, 13D, 14B, 14C, 14D illustrate fragmentary cross-sectional views of a device undergoing various fabrication processes in the method of FIG. 1 and along cut B-B of FIG. 2.

Referring now to FIGS. 3A and 3B, an embodiment of the device 200 including a substrate 300, isolation regions 302 interposing portions of the substrate 300 denoted 300′ providing fin type regions (e.g., active regions) extending from the substrate 300.

The substrate 300 may include an elementary (single element) semiconductor, such as silicon (Si), germanium (Ge), and/or other suitable materials; a compound semiconductor (i.e., alloy semiconductor), such as silicon carbide (SiC), gallium arsenic (GaAs), gallium phosphide (GaP), indium phosphide (InP), indium arsenide (InAs), indium antimonide (InSb), silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), and/or other suitable materials. The substrate 300 may be a single-layer material having a uniform composition. Alternatively, the substrate may include multiple material layers having similar or different compositions suitable for IC device manufacturing. In one example, the substrate may be a silicon-on-insulator (SOI) substrate having a silicon layer formed on a buried silicon oxide (BOX) layer. In some embodiments, the substrate includes various doped regions, such as n-type wells or p-type wells. The doped regions may be doped with n-type dopants, such as phosphorus (P) or arsenic (As), and/or p-type dopants, such as boron (B) or BF₂, depending on design requirements. Doped regions may be formed by implantation of dopant atoms, in-situ doped epitaxial growth, and/or other suitable techniques. In an embodiment, the substrate 300 includes silicon (Si).

As shown in FIGS. 3A-3B, each fin-shaped structure 300′ extends vertically along the Z direction from the substrate 300 and extends lengthwise along the Y direction. The fin-shaped structures 300′ may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

The isolation feature 302 may also be referred to as a shallow trench isolation (STI) feature 302. The isolation feature 302 may be formed using CVD, subatmospheric CVD (SACVD), flowable CVD, spin-on coating, and/or other suitable process. Then the deposited dielectric material is planarized and/or recessed to form the isolation feature 302 having the fin structure 300′ extending there above. The dielectric material for the isolation feature 302 may include silicon oxide, silicon oxynitride, fluorine-doped silicate glass (FSG), a low-k dielectric, combinations thereof, and/or other suitable materials. The isolation feature 302 may include a multi-layer structure including for example, liner layers and fill layers.

The gate structures 206 include a gate dielectric layer 206Ud/206Ld and a gate electrode layer 206Ue/206Le respectively. The dielectric layer 206Ud and/or 206Ld is formed of high-K dielectric materials. As used and described herein, high-k dielectric materials include dielectric materials having a high dielectric constant, for example, greater than that of thermal silicon oxide (˜3.9). In an implementation, the gate dielectric layer 206Ue/206Le includes hafnium oxide. Alternatively, the gate dielectric layer 206Ue/206Le may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The gate electrode layer 206Ue and/or 206Le provide a suitable work function for the respective device. In an embodiment, a p-type work function layer 206Le and a n-type work function layer 206Ue are provided. The gate electrode layer 206Ue/206Le may include a single layer or alternatively a multi-layer structure. By way of example, the p-type work function material may include titanium nitride (TiN), tantalum nitride (TaN), ruthenium (Ru),molybdenum (Mo), aluminum (Al), tungsten nitride (WN), zirconium silicide (ZrSi2),molybdenum silicide (MoSi2), tantalum silicide (TaSi2), nickel silicide (NiSi2), other p-type work function material, or combinations thereof. The n-type work function material may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. In some implementations, the gate electrode layer also includes a fill metal layer such as tungsten (W), liner layer(s), adhesion layer(s), barrier layer(s), silicide layer(s), and/or other conductive structures. In some implementations, a capping layer 314 is provided over the gate 206Ue. Gate spacers 304 and inner spacers 306 may be disposed adjacent the gate structure 206. The spacers 304, 306 include a dielectric material. In some embodiments, the spacers 304 and/or inner spacer features 306 include silicon oxide, silicon nitride, silicon oxycarbide, silicon oxycarbonitride, silicon carbonitride, metal nitride, silicon germanium oxide, combinations thereof, and/or other suitable dielectrics. In some implementations, the gate structure 206 is formed by a replacement gate process where a sacrificial dummy gate (e.g., polysilicon gate) is formed and subsequently removed for positioning of the gate structure 206.

Bottom source/drain features 204L may be formed for the lower device 200L. The bottom source/drain features 204L may be formed using an epitaxial process, such as vapor-phase epitaxy (VPE), ultra-high vacuum chemical vapor deposition (UHV- CVD), molecular beam epitaxy (MBE), and/or other suitable processes. The epitaxial growth process may use gaseous and/or liquid precursors, which interact with the composition of the substrate 300 (e.g., fin 300′) as well as exposed surfaces of the channel layers 202L. In an embodiment, the bottom source/drain features 204L are p-type source/drain features and may include germanium, gallium-doped silicon germanium, boron-doped silicon germanium, or other suitable material and may be in-situ doped during the epitaxial process by introducing a p-type dopant, such as boron, or ex-situ doped using a junction implant process.

A bottom contact etch stop layer (CESL) 308L and a bottom interlayer dielectric (ILD) layer 310L are deposited over the bottom source/drain features 204L. The bottom CESL 308L may include silicon nitride, silicon oxynitride, and/or other materials and may be formed by CVD, ALD, plasma-enhanced chemical vapor deposition (PECVD) process and/or other suitable deposition or oxidation processes. The bottom ILD layer 310L may include materials such as tetraethylorthosilicate (TEOS) oxide, un-doped silicate glass, or doped silicon oxide such as borophosphosilicate glass (BPSG), fused silica glass (FSG), phosphosilicateglass (PSG), boron doped silicon glass (BSG), and/or other suitable dielectric materials and may be formed by CVD, ALD, PECVD processes and/or other suitable deposition processes.

Upper source/drain features 204U may be formed for the upper device 200U. The upper source/drain features 204U may be formed using an epitaxial process, such as VPE, UHV-CVD, MBE, and/or other suitable processes. The epitaxial growth process may use gaseous and/or liquid precursors, which interact with exposed surfaces of the channel layers 202U. In an embodiment, the upper source/drain features 204U are n-type features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. An upper CESL 308U and upper ILD layer 310U may be formed over the source/drain features 204U and may be substantially similar to the bottom CESL 308L and bottom ILD layer 310L respectively.

In some implementations, a leakage block layer includes an undoped semiconductor material, such as undoped silicon (Si), undoped silicon germanium (SiGe), or undoped germanium (Ge) that may be formed in the fin. In these embodiments, the leakage block layer may be deposited using vapor-phase epitaxy (VPE), ultra-high vacuum chemical vapor deposition (UHV-CVD), molecular beam epitaxy (MBE), and/or other suitable epitaxy deposition processes. Spacers or blocking material 318 may be disposed adjacent the bottom source/drain feature 204L.

In some implementations, contact features of the device may include a conductive fill portion and a liner layer such as a silicon nitride. liner and a conductive fill portion may include ruthenium (Ru), nickel (Ni), cobalt (Co), copper (Cu), combinations thereof, and/or other suitable materials. The contact features may provide an interconnection to a feature of the device such as a source/drain region (e.g., 204L).

It is noted that while the device 200 as illustrated in FIGS. 2, 3A, 3B illustrates a C-FET of an exemplary configuration, other device types and other configures may also be possible. For example, in some implementations, other devices having a first epitaxial region and an overlying second epitaxial region where processing is selective between the two epitaxial regions.

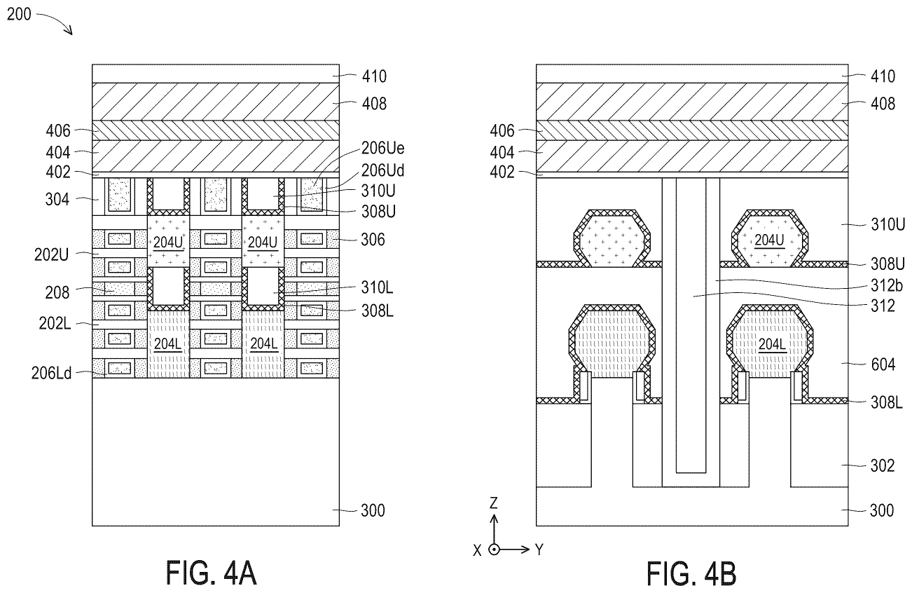

The method 100 includes block 104 where dielectric layer(s) and/or hard mask layer(s) are formed over the device. Referring to the example of FIGS. 4A and 4B, dielectric and/or hard mask layers 402, 404, 406 and 408 are illustrated. In an embodiment, layer 402 is an etch stop layer. In some implementations, the layer 402 is substantially similar to the CESL 308L and/or 308U. In an embodiment, layer 404 is an interlayer dielectric (ILD). In some implementations, the layer 404 is substantially similar to the ILD 310L and/or ILD 310U. In some implementations, the layer 406 and/or 408 are patterning layers provided for reproducing a pattern from an overlying photosensitive layer such as layer 410. In an embodiment, the layer 406 and/or 408 are a hard mask layer. In an embodiment, the layer 408 includes a-silicon. In an embodiment, layer 406 is a silicon nitride and layer 408 is a silicon oxide. Though other compositions are possible. Patterning layer 410 is disposed over the device and stack of dielectric/hard mask layers. In an embodiment, the patterning layer 410 includes a photosensitive material such as a photoresist.

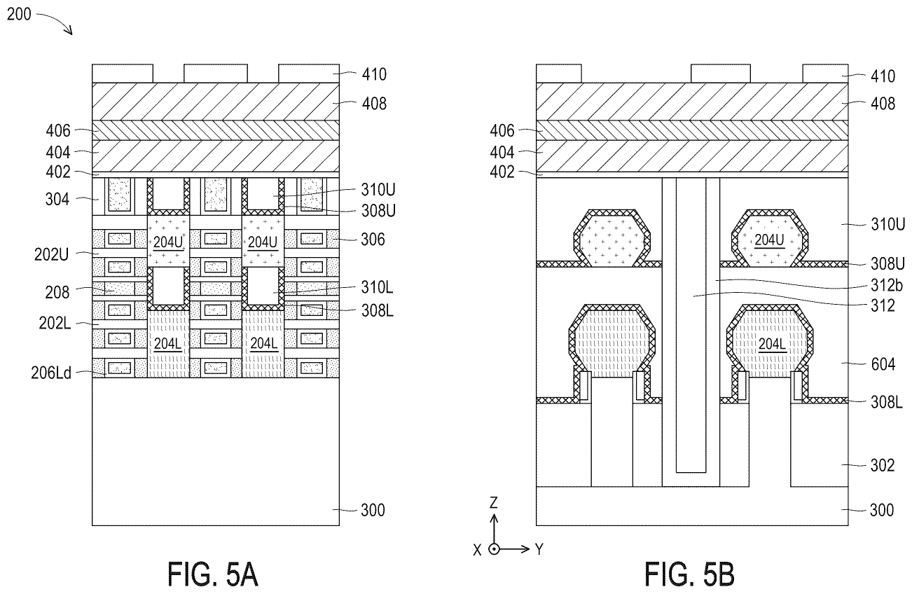

Using photolithography and etching processes, the patterning layer 410 is patterned to provide a plurality of features defining a contact scheme for the device 200. In some implementations, the contact scheme includes the contacts for the source/drain regions of the C-FET device 200. The patterned layers are illustrated in an example at FIGS. 5A, 5B. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. In an embodiment, the patterning processes provide openings corresponding to contact features desired for the source/drain features of the device 200. In some implementations, at least one contact feature is provided to couple a source/drain region of the lower device with the source/drain feature of the upper device.

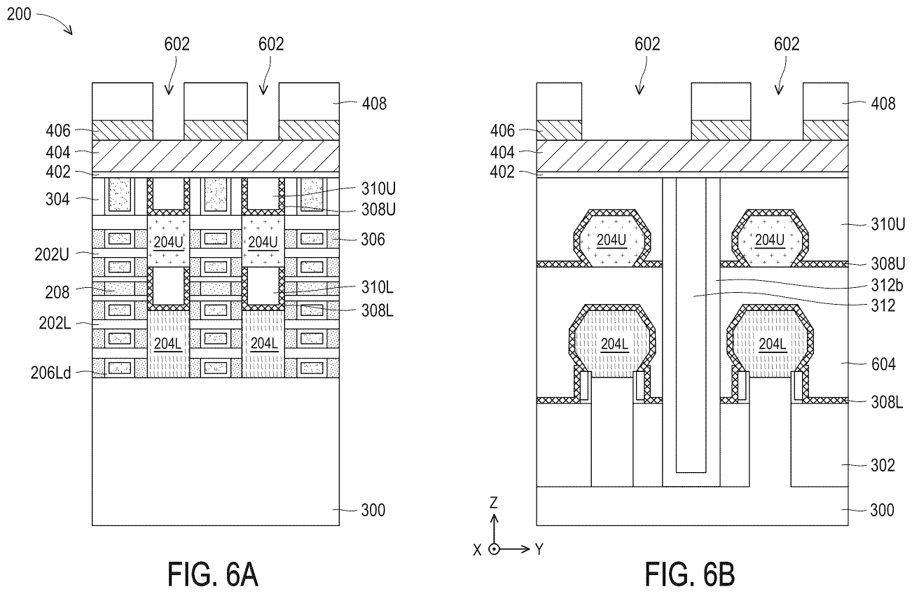

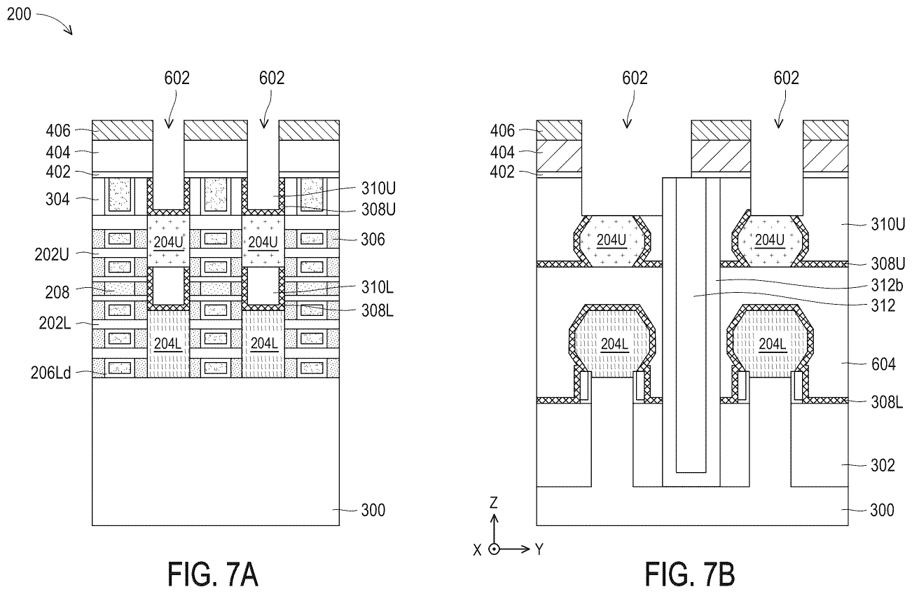

The method 100 includes block 106 where the source/drain contact openings are formed. In some implementations, the source/drain contact openings are provided as defined by the patterned layers of block 104, discussed above. Referring to the example of FIGS. 6A and 6B, openings 602 are formed first in layers 406 and 408 above the C-FET device 200. The openings 602 may correspond with the desired source/drain contacts. Referring to the example of FIGS. 7A and 7B, openings 602 are extended through the dielectric stack 402, 404, 406 to form openings 602 that expose a top surface of the upper source/drain feature 204U. In some implementations, the patterning of block 106 includes patterning a source/drain contact opening extending to one or more or all of the top source/drain features of the upper device.

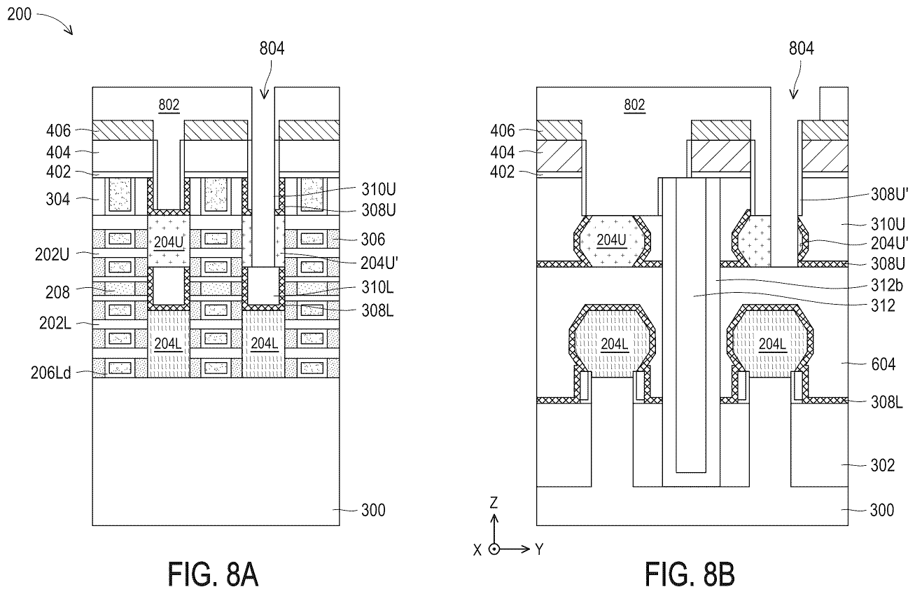

The method 100 includes a block 108 where a dummy patterning layer or sacrificial layer is deposited in the source/drain contact openings formed in block 106. In some implementations, the dummy patterning layer is a bottom anti-reflective coating (BARC) material. Referring to the example of FIGS. 8A and 8B, the openings 602 are filled with patterning material 802. In some implementations, a dielectric (illustrated as 308′) may be formed between the patterning material 802 and the underlying layers. The dielectric may be substantially similar to the ILD, CESL, and/or omitted.

The method 100 includes block 110 where a select source/drain contact opening is patterned from the openings provided in block 106. In some implementations, the patterning of block 110 includes patterning a source/drain contact opening that is intended to extend to a source/drain feature of the bottom device.

After filling the openings of block 106 with patterning material 802 in block 108, a patterning process of block 110 is performed to define a source/drain contact opening 804 for a contact extending from the upper source/drain feature 204U to contact the bottom source/drain feature 204L. In some implementations, a photolithography patterning process defines the opening in patterning layers disposed over the patterning material 802, which are used as masking elements when etching the opening 804 in the patterning material 802. In an embodiment, the opening 804 is first etched to the upper CESL 308U and/or the upper ILD 310U as illustrated in FIGS. 8A and 8B. Portions of the upper source/drain feature 204U are removed to provide 204U′.

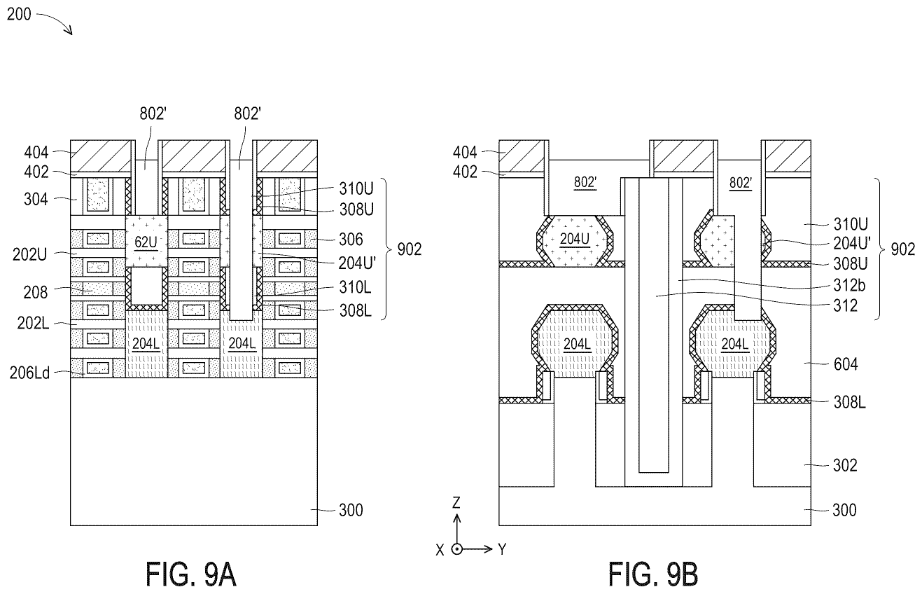

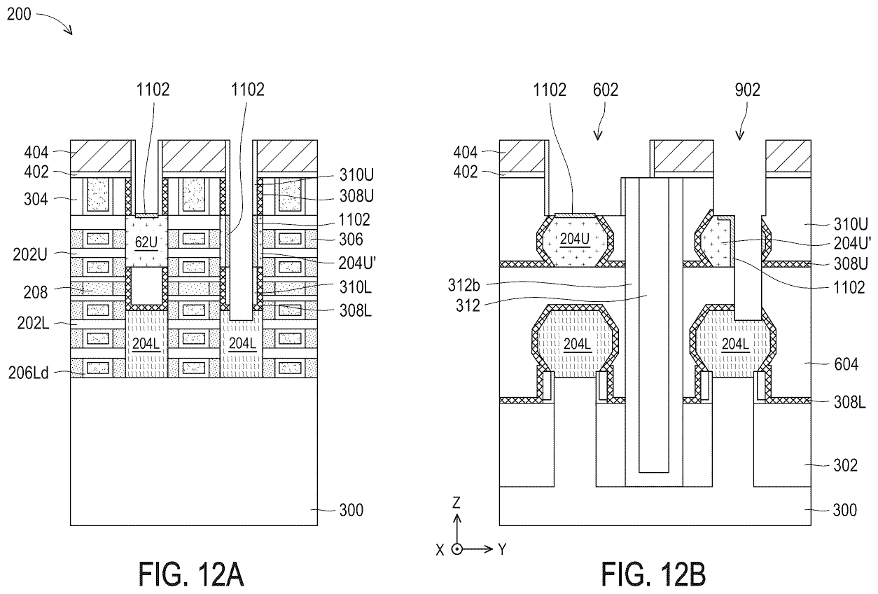

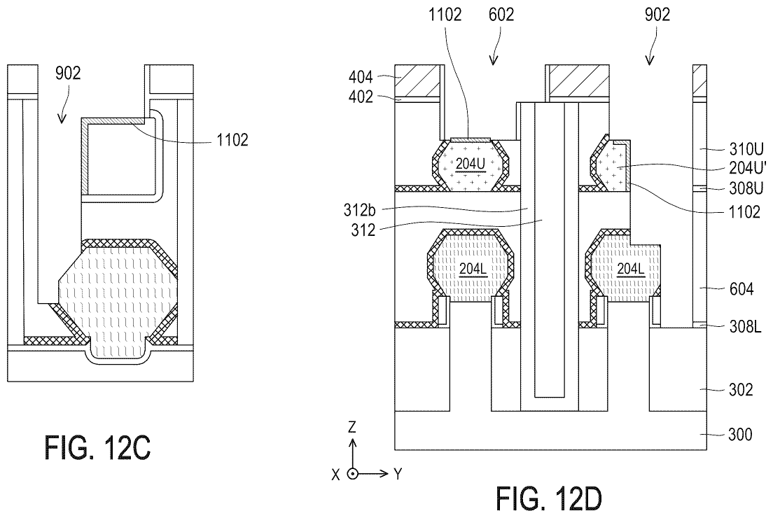

In some implementations of block 110, the opening 804 is then extended to expose an upper surface of the bottom source/drain feature 204L illustrated as opening 902. The opening may continue to etch into an uppermost surface of the bottom source/drain feature 204L to provide an overetch region as illustrated in FIGS. 9A and 9B, which illustrate contact opening 902′ extending into the bottom source/drain feature 204L. In some implementations, the opening 902 exposes a sidewall of the bottom source/drain feature 204L See, e.g., FIG. 12C. In some further implementations, the opening 902 exposes a sidewall of the bottom source/drain feature 204L and extends into dielectric materials (e.g., ILD 310L, 308L) below the bottom source/drain feature 204L. See, e.g., FIG. 12D.

After forming the opening 902 extending to the bottom source/drain feature 204L, layer 406 may be removed from the device 200. The dummy patterning layer 802 may be maintained and/or additional dummy patterning layer 802′ may be included in the opening 902 extending to the bottom source/drain feature 204L for protection during processing. The patterning material 802, 802′ may then be removed.

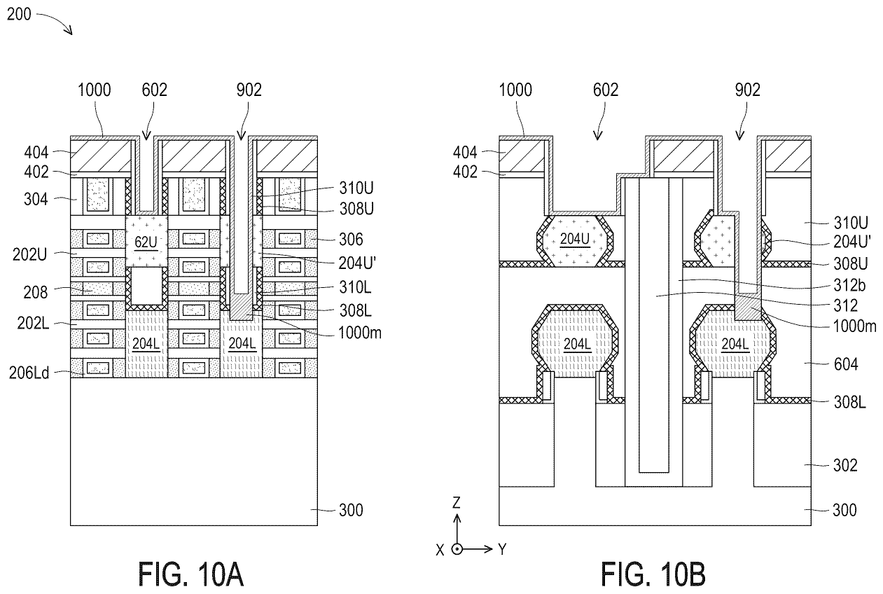

The method 100 includes block 112 including forming a liner layer along the surfaces of the contact openings. In an embodiment, the liner layer is formed along the sidewalls of the contact openings and a bottom surface of the contact openings. Referring to the example of FIGS. 10A and 10B, a liner 1000 is deposited along the openings 602 and 902. In an embodiment, the liner layer 1000 is deposited in openings 602 including on an exposed surface of the upper source/drain feature 204U. In an embodiment, the liner layer 1000 is deposited in openings 902 including an exposed surface of the lower source/drain feature 204L and exposed surface(s) of the upper source/drain feature 204U. In an implementation, the liner layer 1000 is conformally deposited. In an embodiment, the liner layer 1000 is deposited by atomic layer deposition (ALD). An exemplary thickness of the liner layer 1000 is between approximately 1 nanometer (nm) and approximately 5 nm. In some implementations, the thickness of the liner layer 1000 is determined based on the desired conditioned or passivation region desired (discussed below), a thicker liner layer 1000 can reduce the thickness of the conditioned layer. Exemplary compositions for the liner layer 1000 include Al₂O₃, ZrO, SiN, combinations thereof, and/or other suitable dielectrics.

It is noted as illustrated in FIGS. 10A and 10B, the liner layer 1000 includes merged portions 1000m disposed at a bottom of the opening 902. In an embodiment, the merged portion 1000m includes a thickness such that an upper surface of the merged portion 1000m is higher than an upper surface of the bottom source/drain feature 204L. In an embodiment, the merged portion 1000m includes a thickness such that an upper surface of the merged portion 1000m is higher than the bottom CESL 308L. In an embodiment, the merged portion 1000m includes a thickness (e.g., measured vertically) of between approximately 2 nm and approximately 20 nm. The merged portion 1000m provides a liner layer 1000 thickness adjacent the bottom source/drain feature 204L that is greater than the thickness of the liner layer 1000 adjacent the top source/drain feature 204U. That is, the thickness of the liner layer 1000 as measured from the surface of the epitaxial feature outwards is greater at the lower device.

The method 100 includes block 114 where a plasma treatment is performed. The plasma treatment introduces ions to the liner layer described above with reference to block 112. In an embodiment, the plasma treatment includes introduction of nitrogen (N), oxygen (O), fluorine (F), chlorine (Cl), or other suitable plasma.

The introduction of the plasma treatment results in a plasma treated liner layer 1100, referred to as a treated liner 1100. The treated liner 1100 may be comprised of AlxOyNz, AlxOyFz, AlxOyClz, ZrxOyNz, ZrxOyFz, ZrxOyClz, SixNyOz, SixNyFz, SixNyClz, where x, y and z are greater than 0, and/or other suitable materials. In an embodiment, the material of the plasma treated liner layer 1100 may be the material of the liner layer 1000 having an additional atomic element originating from the plasma (e.g., N, O, F, Cl).

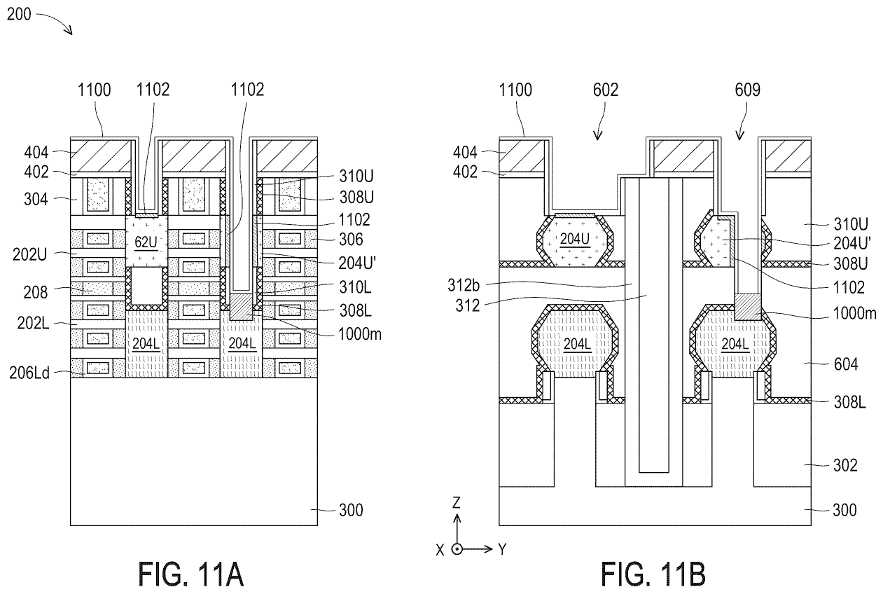

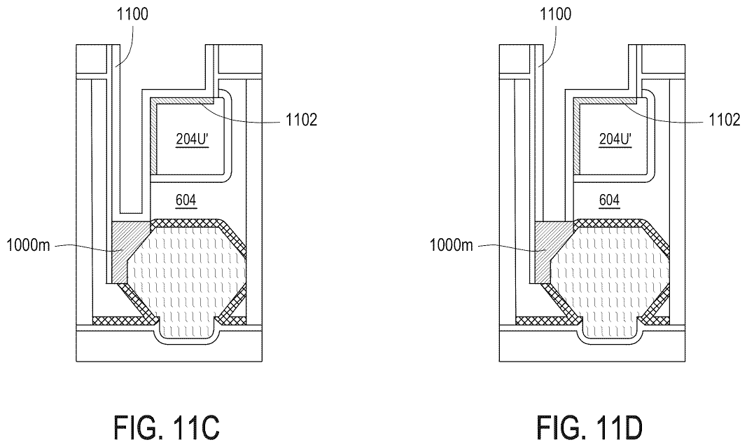

In some implementations, the plasma treatment forms a conformal treated layer 1100 across the device 200. In some implementations, the plasma treatment is directional such that portions of the liner layer 1000 remain untreated. For example, the liner layer 1000 at the bottom of the opening 904 may be untreated. That is a top surface of the liner layer merged portion 1000m in some implementations remains untreated. See FIG. 11D. In some implementations, a top surface of the liner layer 1000m is treated. See FIG. 11C. The treated liner layer 1100 may be approximately 1 nm to 5 nm in thickness. The directional treatment may be achieved by tuning of plasma parameters power and/or bias voltage to control the treatment location including as illustrated in the present figures.

In some implementations, plasma species may penetrate the liner layer 1000 when forming the treated liner layer 1100 to provide a conditioned region 1102 of a semiconductor material underlying the liner layer 1000. The conditioned region 1102 may also be referred to as a passivation region. As an example, the treatment of the liner layer 1000 over the upper source/drain feature 204U may result in a conditioned region 1102 of the upper source/drain feature 204U. In some implementations, the upper source/drain feature 204U includes silicon composition (e.g., silicon doped with phosphorous) prior to the plasma treatment of block 114. The conditioned region 1102 is formed of the upper source/drain feature 204U such that the conditioned region 1102 includes silicon and one or more atomic species present in the plasma. For example, the condition region 1102 may include SiNx, SiOx, SiFx, SiClx, where x is greater than zero. In some implementations, the conditioned region 1102 interfaces a Si:P (e.g., silicon doped with P) portion of the upper source/drain feature 204U. A thickness of the conditioned region 1102 may be approximately 1 nm to 5 nm in thickness.

In an embodiment, the treated liner layer comprises AlON; the conditioned region 1102 comprises SiN; and the upper source/drain 204 comprises silicon (e.g., epitaxially grown silicon and suitable dopants such as phosphorous).

Exemplary conditions for the plasma treatment include a treatment of between approximately 2500 seconds and approximately 4500 seconds. In an embodiment, the treatment is approximately 3600 seconds. Exemplary conditions for the plasma treatment include a treatment at a pressure between approximately 10 Pa and 150 Pa. In an embodiment, the treatment pressure is between approximately 20 Pa and 130 Pa. Exemplary conditions for the plasma treatment include a treatment at a power between approximately 1000 Watts and approximately 4000 Watts. In an embodiment, the treatment is approximately 1500 Watts. In an embodiment, the treatment is approximately 2500 Watts or 3300 Watts. In an embodiment, the plasma is approximately 2% He/N2. In an embodiment, the plasma is approximately 10% Ar/N2. In a further embodiment, the plasma is between approximately 15% Ar/N2 and approximately 25% Ar/N2.

In an embodiment, the plasma is performed with a microwave source, a source frequency of approximately 2.45 GHz, and a source power between approximately 1 and approximately 5 KW. In an embodiment, the plasma is performed with capacitively coupled plasma (CCP), a bias frequency of approximately 13.56 MHz, and a power of between approximately 0 and 1000 Watts.

The method 100 includes block 116 where the liner layer is removed. Block 116 may be performed after block 114. In some embodiments, the treated portion of the liner layer and the untreated portions of the liner layer are both removed. The removal may be performed by a wet etching process. In some implementations, the removal of the liner layer (e.g., treated and/or untreated) may be selective to other layers such as, for example, selective to the conditioned region of the upper source/drain feature such that the conditioned regions are not etched. The removal may be performed by a dilute hydrofluoric (dHF) etch. After the etching process, the conditioned region such as the region comprising a plasma introduced element (e.g., SiNx) remains on the device.

Referring to the example of FIGS. 12A and 12B, the liner layer 1000 and the treated liner 1100 are removed from the device 200. The conditioned region 1102 remains on the upper source/drain feature 204U. In some implementations, the CESL 308L/308U, ILD 310L/310U, dielectric layers 402 and 404 also remain substantially unetched.

The method 100 includes block 118 where an additional epitaxial growth process is performed. In an embodiment, the additional epitaxial growth process grows epitaxial material from a seed of an exposed surface of the lower source/drain feature 204L. As illustrated in the examples of FIGS. 12A, 12B, 12C and 12D and the discussion of block 116, the liner layer has been removed from the device 200, which exposes a surface of the lower source/drain feature 204L. In an embodiment, the additional epitaxial growth includes epitaxial growth of silicon and/or germanium with an p-type dopant. In an embodiment, the additional epitaxial growth includes silicon, germanium (Ge) at an atomic percentage of between approximately 20 and 60%. In a further embodiment, a boron dopant at a concentration of between approximately 1E20 and 9E20 is also provided. In some implementations, the dopant is provided in situ during the growth. The additional epitaxial material may include a same dopant type as the material of the lower source/drain feature 204L.

During the additional epitaxial growth process, the conditioned region 1102 is provided over the upper source/drain feature 204U. The conditioned region 1102 acts as a passivation inhibiting and/or preventing epitaxial growth on the upper source/drain feature 204U during the additional epitaxial growth on the lower source/drain feature 204L. Thus, in some implementations, the additional epitaxial growth can be targeted to the device type of the bottom device.

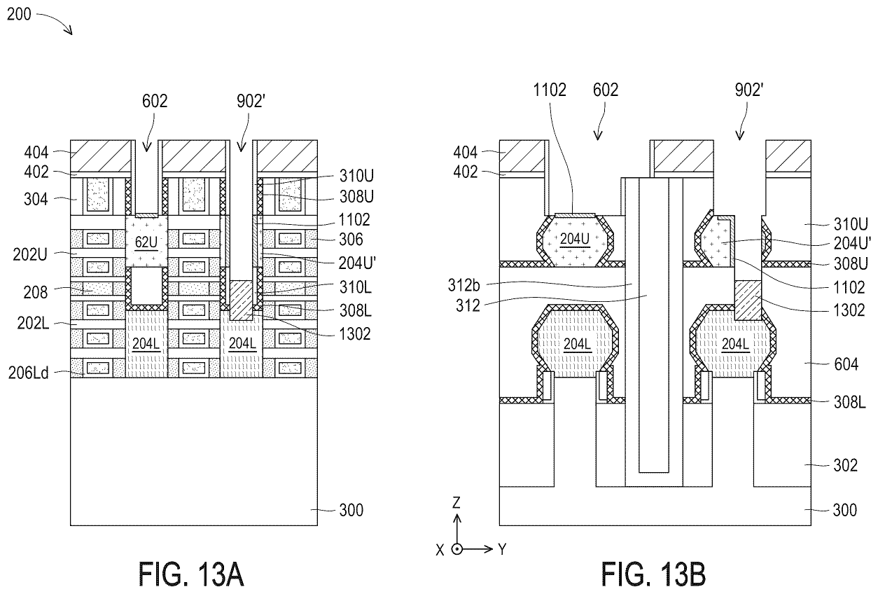

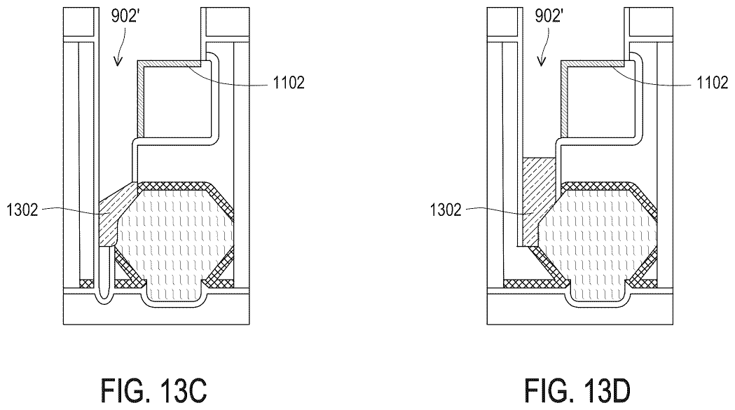

Referring to the examples of FIGS. 13A, 13B, 13C, and 13D, an additional epitaxial portion 1302 is grown on the lower source/drain feature 204L. The additional epitaxial portion 1302 may extend to an opposing sidewall of the opening 902. Thus, in some implementations, a portion of the opening 902 is blocked. The additional epitaxial portion 1302 reduces the depth of the previous contact opening 902 to modified contact opening 902′ having a bottom surface of a top surface of the additional epitaxial portion 1302. The opening 902′ has an aspect ratio reduced from the opening 902. This may provide a benefit in the gap fill of conductive material discussed below.

In some implementations, the epitaxial growth of block 118 includes a low temperature epitaxial growth. In an embodiment, the process temperature is between about 300 Celsius and 500 Celsius. In an embodiment, a low temperature epitaxial growth is considered a growth process less than approximately 600 Celsius. Exemplary precursors for the epitaxial growth include dichlorosilane (DCS), trichlorosilane (TCS), and/or other suitable precursors. In an embodiment, DCS or TCS precursors are provided in the epitaxial growth process. In some implementations, a conditioned region comprises H or Cl surfaces inhibiting growth. In an embodiment, a hydrogen-based precursor is provided in the epitaxial growth process. In some implementations, a conditioned region comprises SiH4-nCln and the hydrogen-based precursor is provided. The Clx groups are inert to the hydrogen-based precursor inhibiting growth.

The method 100 includes block 120 where the contact openings are filled with conductive material to form conductive contacts. In an embodiment, the conditioned region on the upper source/drain region is removed prior to the deposition of conductive material. The conditioned region may be removed by suitable wet etching selective to the conditioned material composition.

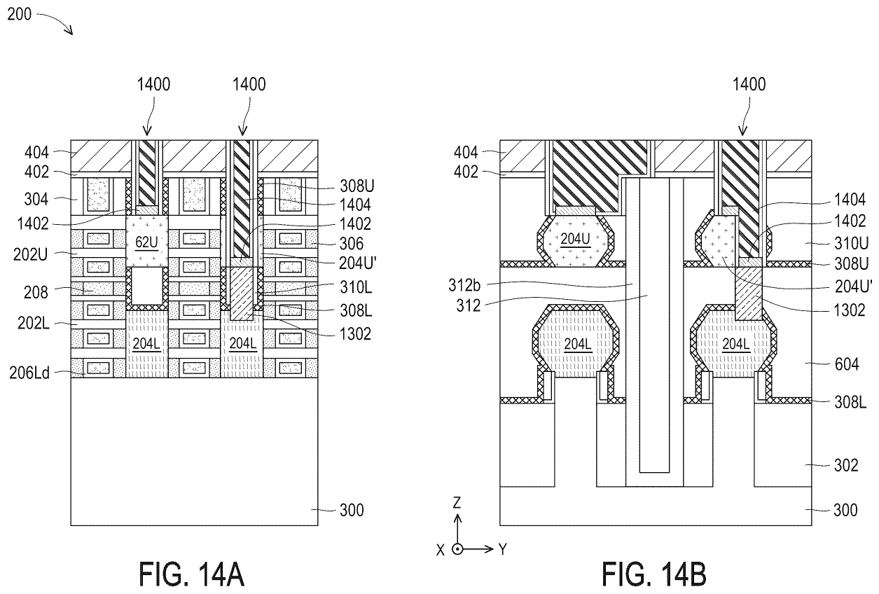

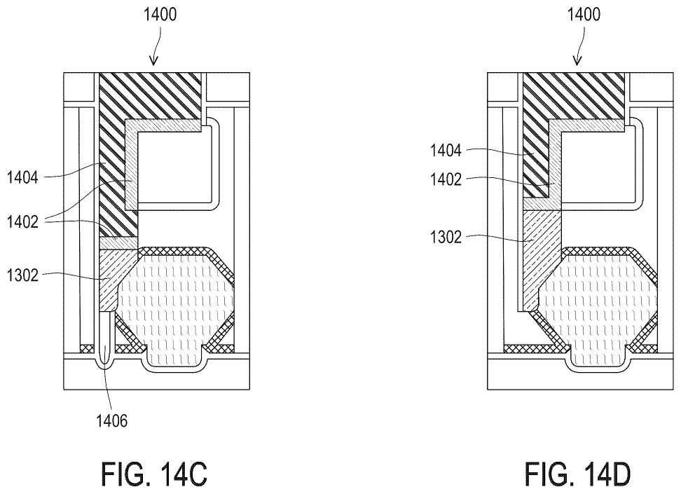

In some implementations, the contacts are formed by first forming a silicide layer on the upper source/drain feature 204U and the lower source/drain feature 204L. In an embodiment, the silicide is a titanium silicide. In some implementations, the silicide is formed concurrently or after the filling with a metal. A fill metal may include a suitable conductive material such as tungsten (W), cobalt (Co), Mo, Ru, and/or other suitable materials. Liner or barrier layers may be formed prior to the fill metal. Referring to the example of FIGS. 14A, 14B, 14C, and 14D, the openings 902′ and 602 are filled with conductive material to form source/drain contacts 1400. The source/drain contacts include a silicide layer 1402 and a fill layer 1404. As discussed above, one or more other conductive layers may also be included in the contacts 1400. In an embodiment, the contact opening 902′ is filled with conductive material to provide a coupling of the upper source/drain feature 204U and the lower source/drain feature 204L. Depending on the growth of the additional epitaxial portion, the silicide layer 1402 may be contiguous between the upper source/drain feature 204U and the lower source/drain feature 204L as illustrated in FIG. 14D. In some implementations, the opening 902′ extends below the lower source/drain feature 204L as discussed above. In such an implementation, a gap may be disposed below the additional epitaxial portion 1302. FIG. 14C illustrates a gap 1406. In an embodiment, the gap is an air gap.

One or more embodiments of the present disclosure may provide benefits of allowing selective epitaxial growth one device type. The selective growth may serve to reduce the aspect ratio that is required of the fill metal in block 120. Further, the selective growth in some implementations provides a performance boost to the device having highly doped epitaxial material. In some implementations, there is a reduction of in the resistance of the source/drain contact e.g., Rcsd.

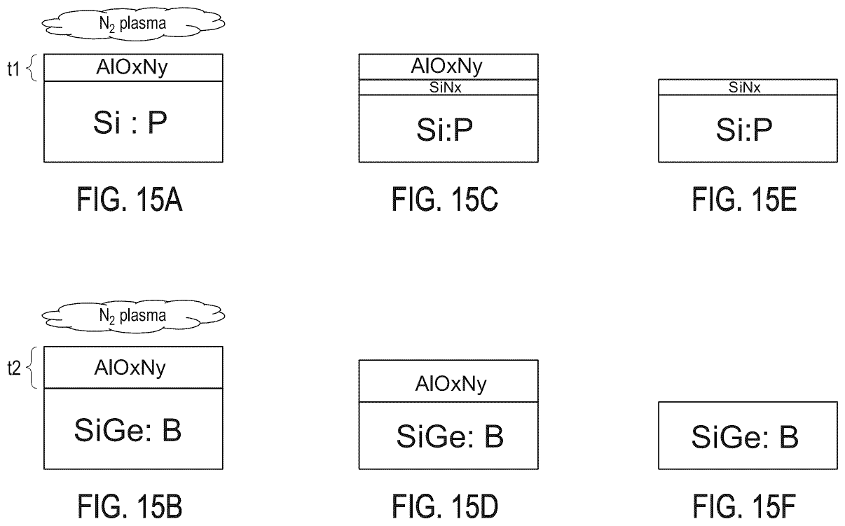

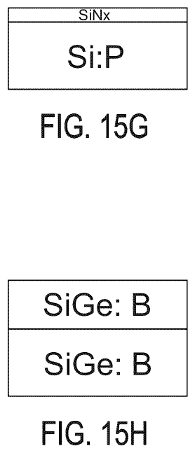

Referring now to FIGS. 15A-15H, illustrated is an embodiment of an exemplary semiconductor feature 1502 in FIGS. 15A, 15C, 15E, and 15G and an exemplary semiconductor feature 1504 in FIGS. 15B, 15D, 15F, and 15H. In an embodiment, the semiconductor feature 1502 is an epitaxial feature suitable for a first device type. For example, in an embodiment, the semiconductor feature 1502 is an n-type epitaxial material such Si doped with phosphorous (or other suitable dopant). In an embodiment, the semiconductor feature 1502 provides a source/drain region for a transistor device such as, for example, the source/drain feature 204U discussed above. In an embodiment, the semiconductor feature 1504 is an epitaxial feature suitable for a second device type. For example, in an embodiment, the semiconductor feature 1504 is an p-type epitaxial material such Si and Ge doped with boron (or arsenic or other suitable dopant). In an embodiment, the semiconductor feature 1504 provides a source/drain region for a transistor device such as, for example, the source/drain feature 204L discussed above. The semiconductor features 1502 and 1504 may be present on a same substrate.

A liner layer is disposed on the top surface of each of the semiconductor feature 1502 and the semiconductor feature 1504. In an embodiment, the thickness of the liner layer formed over the semiconductor feature 1502 is T1. In an embodiment, the thickness of the liner layer formed over the semiconductor feature 1504 is T2. Thickness T2 is greater than thickness T1. In an embodiment, thickness T2 is at least two times the thickness T1. In an embodiment, the liner layer may be substantially similar to the liner layer 1000 discussed above. In an embodiment, the liner layer as deposited includes aluminum oxide. However, other compositions are possible including as discussed above.

In FIGS. 15A and 15B, a plasma treatment is performed, which may be substantially similar to the plasma treatment of block 114 of FIG. 1 discussed above. In an embodiment as illustrated the plasma is an N₂ plasma. In an embodiment, the treated plasma layers include AlOxNy as illustrated in FIGS. 15A and 15B. However, numerous other compositions are possible including as discussed above.

FIGS. 15C and 15D illustrate the semiconductor features 1502 and 1504 respectively after the performance of the plasma treatment. As illustrated in FIG. 15C, for a liner layer with thickness T1, a passivation or conditioned layer is formed between the plasma treated liner layer and the semiconductor feature 1502. The conditioned layer may be formed by introduction of plasma species into the semiconductor feature 1502, for example, by penetrating through the liner layer of thickness T1. In an embodiment, the conditioned layer is SiₓN. However, numerous other compositions are possible including as discussed above. As illustrated in FIG. 15D, for a liner layer with thickness T2, the semiconductor feature 1504 is unchanged.

FIGS. 15E and 15F illustrate a removal of the plasma treated liner layer. In an embodiment, FIGS. 15E and 15F are substantially similar to block 116 of the method 100 in FIG. 1. In some implementations, the removal is by wet etching selective to the plasma treated liner layer.

FIGS. 15G and 15H illustrate the semiconductor features 1502 and 1504 respectively after an epitaxial growth process. In an embodiment, the epitaxial growth process may be substantially similar to block 118 of the method 100 of FIG. 1. In some implementations, an epitaxial material having the same dopant type as the semiconductor feature 1504 is grown. In a further embodiment, an epitaxial material including silicon, germanium, and a p-type dopant such as boron is formed on the semiconductor feature 1504. Due to the presence of the conditioned layer (e.g., SixN) on the semiconductor feature 1502, no or minimal epitaxial growth occurs on the semiconductor feature 1502.

In one exemplary aspect, the present disclosure is directed to a semiconductor structure. The semiconductor structure includes a first semiconductor device and a second semiconductor device. The first semiconductor device includes a first gate structure, a first source/drain feature, and a second source/drain feature. The second semiconductor device is disposed over the first semiconductor device and includes a second gate structure, a third source/drain feature, and a fourth source/drain feature. An etch stop layer is disposed on a first surface of the first source/drain feature, wherein an epitaxial portion of the first source/drain feature has an uppermost surface above the etch stop layer. A dielectric layer is over the etch stop layer and between the first source/drain feature and the third source/drain feature. And a contact structure extends through the third source/drain feature, the etch stop layer, and the dielectric layer to the epitaxial portion of the first source/drain feature.

In a further embodiment, the contact structure includes a silicide region on the epitaxial portion of the third source/drain feature. And in some implementations, the device includes an air gap disposed below the contact structure. In an embodiment, the epitaxial portion of the first source/drain feature includes epitaxial material comprising silicon and germanium.

In yet another exemplary aspect, the present disclosure is directed to a method. The method includes forming a lower transistor comprising a first channel layer, a first gate structure around the first channel layer, and a first source/drain region. And forming an upper transistor over the lower transistor, the upper transistor comprising a second channel layer, a second gate structure around the second channel layer, and a second source/drain region. An opening is etched extending to expose a surface of the second source/drain region of the upper transistor and a surface of the first source/drain region of the lower transistor. A liner layer is conformably deposited on a sidewall and a bottom of the opening. A plasma treatment is performed on the liner layer-the plasma treatment forms a passivation layer between the liner layer and the second source/drain region of the upper transistor. After performing the plasma treatment, an epitaxial material portion is grown on the surface of the first source/drain region of the lower transistor while the passivation layer is disposed on the second source/drain region.

In a further embodiment, the method includes filling the opening with a conductive material, as the conductive material is disposed on the epitaxial material portion. In some implementations, filling the opening includes forming a silicide on the epitaxial material portion. In an embodiment, conformally depositing the liner layer includes depositing Al2O3, ZrO, or SiN. And in some implementations, forming the passivation layer includes SiNx, SiOx, SiFx, or SiClx where x is greater than zero.

In another of the broader embodiments, a method is provided. The method includes epitaxially growing a first epitaxial feature of silicon and a first dopant type and epitaxially growing a second epitaxial feature of silicon and a second dopant type. The second epitaxial feature is disposed above the first epitaxial feature. A surface of each of the first epitaxial feature and the second epitaxial feature is exposed. And liner layer is deposited on the exposed surfaces where the liner layer is formed having a first thickness over the first epitaxial feature and a second thickness over the second epitaxial feature, the second thickness being less than the first thickness. The method continues to perform a plasma treatment on the liner layer that forms a conditioned region between the liner layer and the second epitaxial feature. The liner layer after the plasma treatment is removed after treatment. And another epitaxial material is grown on the first epitaxial feature while the conditioned region is disposed on the second epitaxial feature.

In a further embodiment, the method includes depositing the liner layer by merging a first portion of the liner layer with a second portion of the liner layer to form the first thickness. In an embodiment, performing the plasma treatment does not form a conditioned region feature on the first epitaxial feature. In some implementations, the exposing the surface of each of the first epitaxial feature and the second epitaxial feature includes etching an opening extending from above the first epitaxial feature to the second epitaxial feature. In an embodiment, growing another epitaxial material includes a low temperature epitaxial growth process. Removing the liner layer may expose the conditioned region. And in some cases the conditioned region inhibits epitaxial growth on the second epitaxial feature during the growing another epitaxial material. In an embodiment, growing the another epitaxial material includes growing a material comprising silicon and the first dopant type. Performing the plasma treatment on the liner layer forms a treated liner layer of at least one of AlxOyNz, AlxOyFz, AlxOyClz, ZrxOyNz, ZrxOyFz, ZrxOyClz, SixNyOz, SixNyFz, or SixNyClz, where x, y and z are greater than zero.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, the method comprising:
forming a first epitaxial region;
forming second epitaxial region, wherein an opening exposes a first surface portion on the first epitaxial region and a second surface portion on the second epitaxial region;
depositing a liner layer on the first surface portion;
performing a plasma treatment, wherein the plasma treatment forms a passivation layer between the liner layer and the first epitaxial region to form a treated surface portion from the first surface portion;
after performing the plasma treatment, removing the liner layer; and
after removing the liner layer, growing an additional epitaxial material portion on the second surface portion of the second epitaxial region while the treated surface portion inhibits epitaxial growth on the first epitaxial region.

2. The method of claim 1, further comprising:
depositing a conductive material on the additional epitaxial material portion.

3. The method of claim 2, wherein the conductive material provides an electrical contact to the first epitaxial region and the second epitaxial region.

4. The method of claim 1, further comprising:
forming a silicide on the additional epitaxial material portion.

5. The method of claim 1, wherein the depositing the liner layer includes depositing Al₂O₃, ZrO, or SiN.

6. The method of claim 1, wherein the forming the treated surface portion includes forming SiNx, SiOx, SiFx, or SiClx where x is greater than zero.

7. The method of claim 1, wherein the forming the first epitaxial region includes forming the first epitaxial region with a first dopant type.

8. The method of claim 7, wherein the forming the second epitaxial region includes forming the second epitaxial region with a second dopant type.

9. A method of fabricating a semiconductor device, comprising:
epitaxially growing a first epitaxial feature, wherein the first epitaxial feature includes silicon and a first dopant type;
depositing a liner layer on an exposed surface of the first epitaxial feature;
performing a plasma treatment on the liner layer, wherein the performing the plasma treatment includes forming a conditioned region between the liner layer and the first epitaxial feature;
removing the liner layer after the plasma treatment; and
performing another epitaxial growth process, wherein during the another epitaxial growth process the conditioned region inhibits growth.

10. The method of claim 9, wherein the performing the plasma treatment on the liner layer forms a treated liner layer of at least one of AlₓO_{y}N_{z}, AlₓO_{y}F_{z}, AlₓO_{y}Cl_{z}, ZrₓO_{y}N_{z}, ZrₓO_{y}F_{z}, ZrₓO_{y}Cl_{z}, SiₓN_{y}O_{z}, Siₓ N_{y}F_{z}, or SiₓN_{y}Cl_{z}, where x, y and z are greater than zero.

11. The method of claim 9, wherein the performing the plasma treatment forms a conditioned region of SiH₄₋ₙClₙ.

12. The method of claim 9, wherein the performing the plasma treatment forms a conditioned region providing a hydrogen (H) comprising surface.

13. The method of claim 9, further comprising:
removing the conditioned region after performing another epitaxial growth process.

14. The method of claim 13, further comprising:
after removing the liner layer and the conditioned region, depositing a conductive material on the first epitaxial feature.

15. The method of claim 9, wherein the performing another epitaxial growth process includes a low temperature epitaxial growth process.

16. A semiconductor device comprising:
a first epitaxial source/drain feature having a first conductivity type;
a second epitaxial source/drain feature having a second conductivity type, the second epitaxial source/drain feature located below the first epitaxial source/drain feature in a cross-sectional view;
a first silicide layer on a first surface of the first epitaxial source/drain feature;
a second silicide layer on a first upper surface of the second epitaxial source/drain feature, wherein a metal layer extends between the first silicide layer and the second silicide layer; and
an air gap disposed below a region of the second epitaxial source/drain feature.

17. The semiconductor device of claim 16, wherein the first surface of the first epitaxial source/drain feature includes a substantially horizontal region and a substantially vertical region in the cross-sectional view.

18. The semiconductor device of claim 16, wherein the first upper surface of the second epitaxial source/drain feature includes a substantially horizontal region in the cross-sectional view.

19. The semiconductor device of claim 16, wherein an uppermost surface of the air gap is defined by the second epitaxial source/drain feature.

20. The semiconductor device of claim 19, wherein in the cross-sectional view, the air gap extends lower than the second epitaxial source/drain feature.
